(19) United States
(12) Patent Application Publication
(10) Pub. No.: US 2023/0402395 A1
(43) Pub. Date: Dec. 14, 2023

(54) SEMICONDUCTOR DEVICE

(71) Applicant: Kioxia Corporation, Tokyo (JP)

(72) Inventors: Kotaro NODA, Yokkaichi Mie (JP); Kyoko NODA, Yokkaichi Mie (JP); Shosuke FUJII, Kuwana Mie (JP); Yusuke ARAYASHIKI, Kawasaki Kanagawa (JP); Hiroyuki ODE, Yokkaichi Mie (JP)

(73) Assignee: Kioxia Corporation, Tokyo (JP)

(21) Appl. No.: 18/331,519

(22) Filed: Jun. 8, 2023

(30) Foreign Application Priority Data
Jun. 10, 2022 (JP) 2022-094032

(51) Int. Cl. H01L 23/544; H10B 63/10; H10B 63/00

(52) U.S. Cl. CPC H01L 23/544; H10B 63/10; H10B 63/24; H10B 63/80; H01L 2223/54426

(57) ABSTRACT

A semiconductor device includes: a semiconductor substrate including a first area and a second area; a plurality of memory cells provided in the first area; a mark provided in the second area and having a first side surface and a second side surface that intersects with the first side surface; and a plurality of patterns provided in the second area and provided on the first side surface and the second side surface.

### CROSS-REFERENCE TO RELATED APPLICATION

This application is based upon and claims the benefit of priority from Japanese Patent Application No. 2022-094032, filed Jun. 10, 2022, the entire contents of which are incorporated herein by reference.

### FIELD

Embodiments described herein relate generally to a semiconductor device.

### BACKGROUND

In general, resistive random access memory (ReRAM) utilizes a change in resistance of a film. As a type of ReRAM, a phase change memory (PCM) using a change in resistance value depending on thermal phase transition between a crystalline state and an amorphous state in a memory area of a film is developed. A superlattice PCM where two different alloys are repeatedly stacked can induce phase change in a film at a low current, and thus attracts attention as a memory device where power consumption can be easily reduced.

### DESCRIPTION OF THE DRAWINGS

FIG. 1 is a top view illustrating a semiconductor device according to an embodiment;

FIG. 2 is a top view illustrating a structure of a memory cell array;

FIG. 3 is a schematic bird's-eye view of a memory cell disposed in the memory cell array;

FIG. 4 is a top view illustrating an alignment mark according to a first embodiment;

FIGS. 5A and 5B are schematic top views illustrating a fine pattern;

FIG. 6 is a schematic cross-sectional view illustrating a stacked structure of the memory cell and the fine pattern;

FIG. 7 is a schematic cross-sectional view illustrating a method of manufacturing the semiconductor device according to the embodiment;

FIG. 8 is a schematic cross-sectional view illustrating the method of manufacturing the semiconductor device according to the embodiment continued from FIG. 7;

FIG. 9 is a schematic cross-sectional view illustrating the method of manufacturing the semiconductor device according to the embodiment continued from FIG. 8;

FIG. 10 is a schematic cross-sectional view illustrating the method of manufacturing the semiconductor device according to the embodiment continued from FIG. 9;

FIG. 11 is a schematic cross-sectional view illustrating the method of manufacturing the semiconductor device according to the embodiment continued from FIG. 10;

FIG. 12 is a top view illustrating an alignment mark according to a comparative example;

FIG. 13 is a top view illustrating an alignment mark according to a first modification example;

FIG. 14 is a top view illustrating an alignment mark according to a second modification example;

FIG. 15 is a top view illustrating an alignment mark according to a second embodiment;

FIG. 16 is a top view illustrating an alignment mark according to a comparative example; and

FIG. 17 is a top view illustrating an alignment mark according to a modification example.

### DETAILED DESCRIPTION

Embodiments provide a semiconductor device capable of reducing dishing and film peeling.

In general, according to one embodiment, a semiconductor device includes: a semiconductor substrate including a first area and a second area; a plurality of memory cells provided in the first area; a mark provided in the second area and having a first side surface and a second side surface that intersects with the first side surface; and a plurality of patterns provided in the second area and provided on the first side surface and the second side surface.

Hereinafter, embodiments will be described with reference to the drawings. In the following description of the drawings, the same or equivalent components will be represented by the same or equivalent reference numerals. It should be noted that the drawings are schematic, and a relationship and the like between the thickness and planar dimensions are different from the real ones.

### First Embodiment

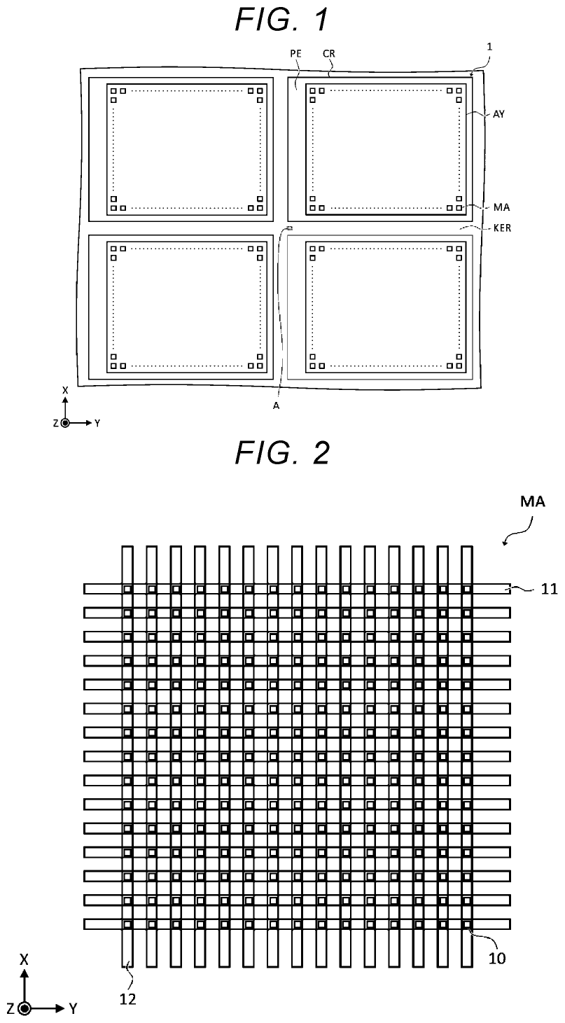

A semiconductor device according to an embodiment will be described with reference to FIG. 1. FIG. 1 is a top view illustrating a layout of the semiconductor device according to the embodiment. In FIG. 1 and subsequent drawings, a plane parallel to a surface of the semiconductor device is assumed to be an X-Y plane.

A semiconductor device 1 includes a plurality of chip areas CR including a cell portion AY and a peripheral portion PE. As illustrated in FIG. 1, a kerf area KER is provided between the chip areas CR. In the cell portion AY, memory cell arrays MA are disposed, for example, in a matrix shape. A structure of the memory cell array MA will be described below.

The peripheral portion PE surrounds the cell portion AY. In the peripheral portion PE, a logic circuit or the like that controls the cell portion AY is disposed.

The kerf area KER functions as a scribe area that is cut by a blade of a dicer in a dicing process. An alignment mark described below is provided in the kerf area KER.

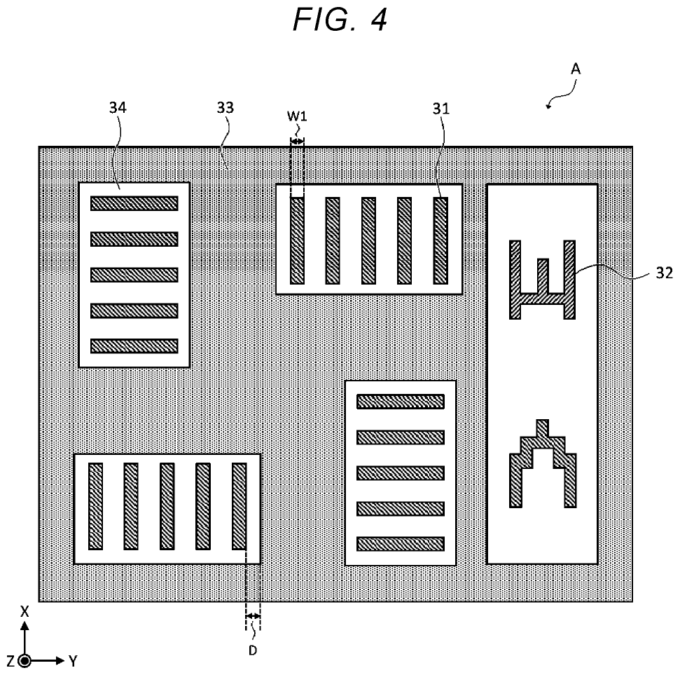

Next, the structure of the memory cell array MA will be described with reference to FIG. 2. FIG. 2 is a top view illustrating the structure of the memory cell array MA. As illustrated in FIG. 4, the memory cell array MA includes a plurality of first wiring layers (bit lines) 11, a plurality of second wiring layers (word lines) 12, and a plurality of memory cells 10 disposed at each intersection between the plurality of first wiring layers 11 and the plurality of second wiring layers 12.

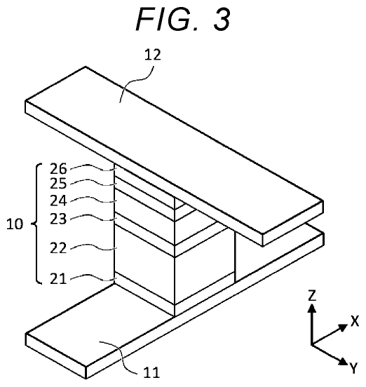

Next, a structure of the memory cell 10 of the semiconductor device according to the embodiment will be described with reference to FIG. 3. FIG. 3 is a schematic bird's-eye view of the memory cell 10 disposed in the memory cell array MA.

The memory cell 10 of the semiconductor device according to the embodiment includes memory elements and a selector 22 that are connected in series between the first wiring layer 11 and the second wiring layer 12 as illustrated in FIG. 3. The memory elements include a resistance change film 24. A conductive film 23 and a conductive film 25 described below may also be considered as memory elements.

The resistance change film 24 can electrically switch between a state (set state) where a resistance is relatively lower and a state (reset state) where a resistance is relatively higher, and stores data in a nonvolatile manner. The selector 22 prevents a sneak current when electrically accessing (forming/writing/erasing/reading) a selected memory cell.

When a reset voltage is applied to the resistance change film 24 in a low resistance state (set state) where the resistance is relatively lower through the first wiring layer 11 and the second wiring layer 12, the resistance change film 24 can switch to a high resistance state (reset state) where the resistance is relatively higher.

When a set voltage higher than the reset voltage is applied to the resistance change film 24 in the high resistance state (reset state), the resistance change film 24 can switch to the low resistance state (set state).

The resistance change film 24 is formed using a superlattice structure where a plurality of layers of chalcogenide compounds are stacked. The chalcogenide compounds used in the resistance change film 24 are configured by two or more chalcogenide compounds, for example, antimony tellurium such as Sb₂Te₃ and germanium tellurium such as GeTe. To stabilize phase change, one of the chalcogenide compounds includes antimony (Sb) or bismuth (Bi).

The selector 22 is formed of a chalcogenide compound of transition metal. The chalcogenide compound is, for example, a compound including one or more transition metals selected from a group consisting of titanium (Ti), vanadium (V), copper (Cu), zinc (Zn), chromium (Cr), zirconium (Zr), platinum (Pt), palladium (Pd), molybdenum (Mo), nickel (Ni), manganese (Mn), and hafnium (Hf) and one or more chalcogen elements selected from a group consisting of sulfur (S), selenium (Se), and tellurium (Te).

The resistance change film 24 is disposed between the conductive film 25 and the conductive film 23. Each of the conductive film 25 and the conductive film 23 is a metal film or a metal nitride film.

An electrode layer 26 is disposed between the conductive film 25 and the second wiring layer 12. For example, tungsten (W), titanium (Ti), tantalum (Ta) or a nitride thereof can be applied to the first wiring layer 11, the second wiring layer 12, and the electrode layer 26.

A conductive film 21 is disposed between the first wiring layer 11 and the selector 22. The conductive film 21 is a metal film or a metal nitride film. The conductive film 21 may be, for example, a conductive material such as titanium nitride (TiN), tungsten (W), copper (Cu), or aluminum (Al). The conductive film 21 is connected to the first wiring layer 11.

The conductive films 21 and 23 prevent diffusion of elements between layers of the selector 22. Likewise, the conductive films 23 and 25 prevent diffusion of elements between layers of the resistance change film 24.

The conductive films 21 and 23 improve adhesion of the selector 22. Likewise, the conductive films 23 and 25 improve adhesion of the resistance change film 24.

Next, an alignment mark according to the first embodiment will be described with reference to FIGS. 4 to 6. The alignment mark according to the first embodiment is used for, alignment or the like of lithography.

First, the alignment mark according to the first embodiment will be described with reference to FIG. 4. FIG. 4 is a diagram illustrating a layout of the alignment mark according to the first embodiment and is an enlarged top view illustrating an area A of FIG. 1. The area A indicates an example of a position of the alignment mark and may be provided at any position in the kerf area KER. A plurality of areas A may be provided.

As illustrated in FIG. 4, the alignment mark according to the first embodiment includes a mark 31 and a text mark 32. The mark 31 is an index for alignment. The text mark 32 is provided for identifying the alignment mark. Each of the mark 31 and the text mark 32 includes a first side surface having a length in the X direction and a second side surface having a length in the Y direction. FIG. 4 illustrates an example where the text mark 32 is provided, but the text mark 32 is not essential. The mark 31 and the text mark 32 are examples of the alignment mark.

In the first embodiment, a plurality of marks 31 and a plurality of text marks 32 may be provided. For example, the marks 31 extend in the X direction and are located at intervals in the Y direction. Alternatively, for example, the marks 31 extend in the Y direction and are located at intervals in the X direction. That is, as illustrated in FIG. 4, by locating a plurality of marks 31 to form a set, an alignment pattern is formed.

As illustrated in FIG. 4, the area A of FIG. 1 further includes a fine pattern 33. The fine pattern 33 is embedded in an area excluding the mark 31, the text mark 32, and the periphery thereof. The fine pattern 33 is provided along the first side surfaces and the second side surfaces of the mark 31 and the text mark 32. An interlayer insulating film 34 is provided between the mark 31, the text mark 32, and the fine pattern 33. The interlayer insulating film 34 includes, for example, an insulating material such as a silicon oxide film. A distance D between the fine pattern 33 and the mark 31 is desirably 2.5 μm or more and 4 μm or less to improve the visibility of the mark 31.

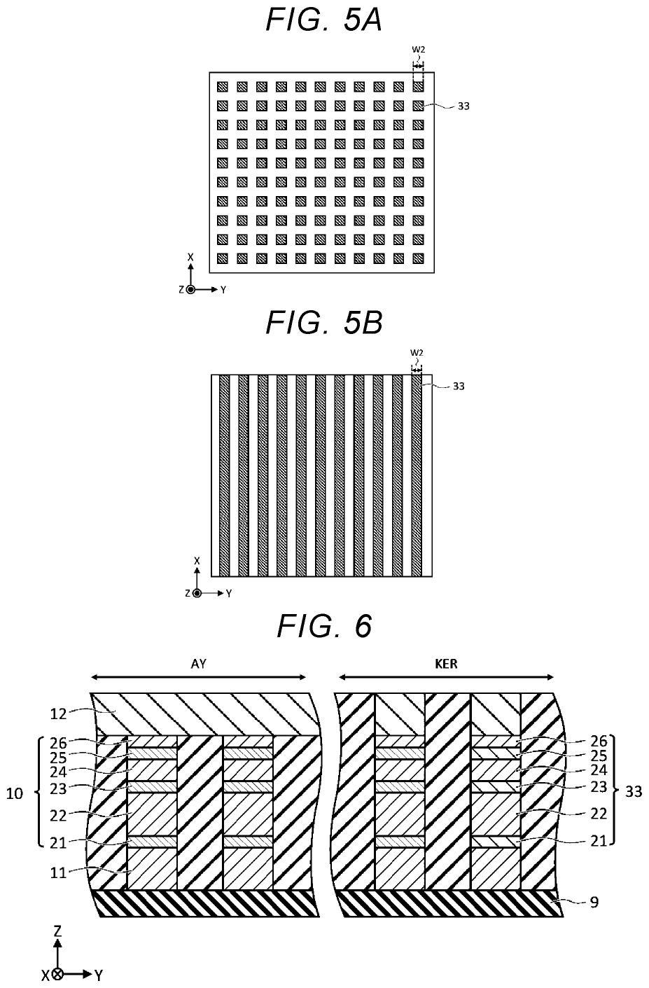

FIGS. 5A and 5B are schematic diagrams illustrating a layout of the fine pattern 33. Examples of the layout of the fine pattern 33 include a layout illustrated in FIG. 5A where the fine patterns 33 are square and are each disposed in a matrix shape and a layout illustrated in FIG. 5B where the fine patterns 33 are linear. Alternatively, both of the layouts illustrated in FIGS. 5A and 5B may be provided. For example, an interlayer insulating film is provided between the fine patterns 33. A width W2 of the fine pattern 33 is desirably less than the width W1 of the mark 31 illustrated in FIG. 4. More specifically, the width W2 is desirably 10 μm or less to improve the visibility of the mark 31.

FIG. 6 is a schematic cross-sectional view illustrating a stacked structure of the memory cell 10 and the fine pattern 33. A stacked film of the memory cell 10 is illustrated in the cell portion AY, and a stacked film of the fine pattern 33 is illustrated in the kerf area KER. As illustrated in FIG. 6, the fine pattern 33 includes a stacked film having substantially the same structure as the stacked film (21, 22, 23, 24, 25, 26) forming the memory cell 10 disposed in the cell portion AY. The mark 31 and the text mark 32 also have substantially the same stacked structure as the memory cell 10 as in the fine pattern 33. Although not illustrated in FIG. 6, for example, a logic circuit that controls the cell portion AY may be disposed between the memory cell 10 and the fine pattern 33.

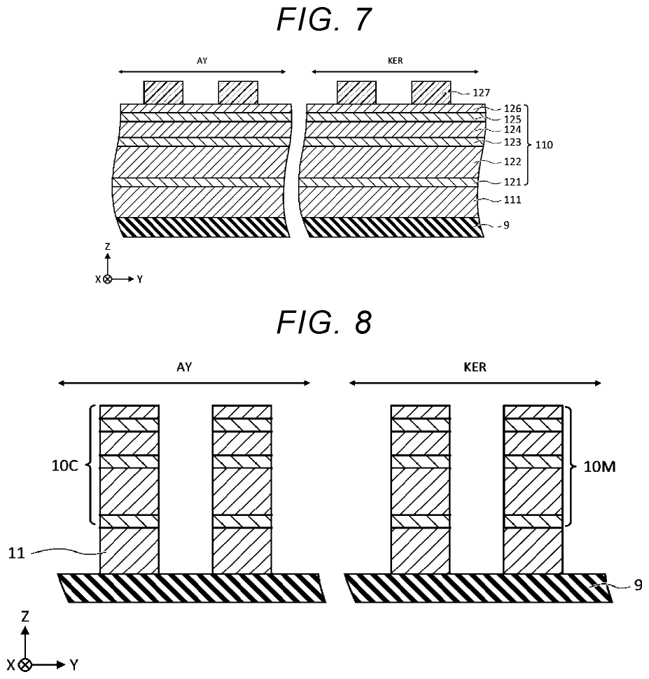

Next, a method of manufacturing the semiconductor device according to the first embodiment will be described with reference to FIGS. 7 to 11.

First, as illustrated in FIG. 7, a first wiring layer 111 is formed on a semiconductor substrate 9 in the cell portion AY and the kerf area KER. A stacked film 110 (121, 122, 123, 124, 125, 126) forming the memory cell 10 and the fine pattern 33 is stacked on the first wiring layer 111. That is, a conductive film 121, a selector 122, a conductive film 123, a resistance change film 124, a conductive film 125, and an electrode layer 126 are formed in order on the first wiring layer 111. A mask 127 is formed by lithography or the like. The semiconductor substrate includes, for example, a silicon substrate.

Next, as illustrated in FIG. 8, for example, by reactive ion etching (RIE), the stacked film 110 and the first wiring layer 111 in the cell portion AY are processed into a linear shape extending in the X direction, and the stacked film 110 and the first wiring layer 111 in the kerf area KER are processed into a matrix shape or a linear shape. As a result, a stacked film 10C is formed in the cell portion AY, and a stacked film 10M is formed in the kerf area KER.

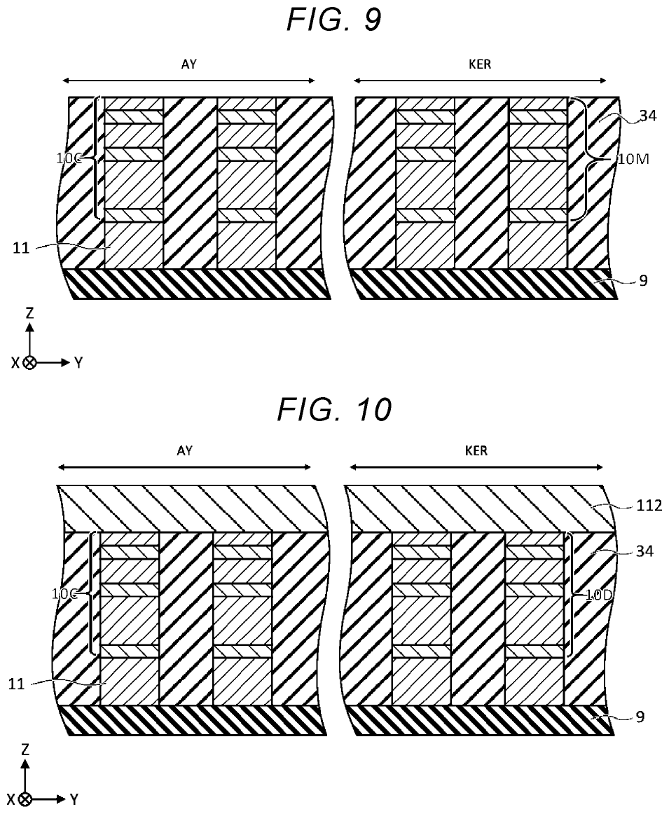

Next, as illustrated in FIG. 9, the interlayer insulating film 34 is formed, and an upper portion thereof is planarized using a chemical mechanical polishing (CMP) technique or the like. As a result, the interlayer insulating film 34 is embedded between the stacked films 10C or between the stacked films 10M.

Examples of the interlayer insulating film 34 include a silicon oxide film and a silicon nitride film, and the interlayer insulating film 34 is formed by, for example, atomic layer deposition (ALD), low pressure chemical vapor deposition (CVD), or flowable CVD.

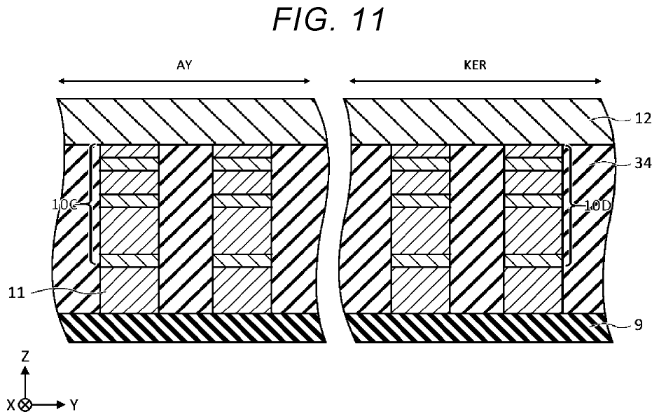

Next, as illustrated in FIG. 10, a metal layer 112 forming the second wiring layer 12 is formed.

Next, as illustrated in FIG. 11, by RIE using a mask (not illustrated), the metal layer 112 in the cell portion AY is processed into a linear shape extending in the Y direction to form the second wiring layer 12. Concurrently, the metal layer 112 in the kerf area KER is processed into a matrix shape or a linear shape. FIG. 11 illustrates a case where both of the metal layer 112 in the cell portion AY and the metal layer 112 in the kerf area KER are processed into a linear shape extending in the Y direction.

The plurality of second wiring layers 12 in the cell portion AY and the kerf area KER are located at intervals in the X direction, and an upper surface of the stacked film 10C (an upper surface of the electrode layer 26) and an upper surface of the interlayer insulating film 34 are exposed between the second wiring layers 12 adjacent to each other in the X direction.

Next, by RIE using a mask (not illustrated), the stacked film and the interlayer insulating film 34 below the gap between the second wiring layers 12 processed in a linear shape are further processed, and the memory cell 10 is formed at intersections between the second wiring layer 12 and the first wiring layer 11. Concurrently, the stacked film 110 and the first wiring layer 111 in the kerf area KER are processed into a matrix shape or a linear shape, and the fine pattern 33 is formed.

The interlayer insulating film 34 is embedded in a space formed by processing and is planarized using a chemical mechanical polishing (CMP) technique or the like. As a result, interlayer insulating film 34 is formed between the second wiring layers 12, between the stacked films 10C, or between the stacked films 10M.

The mark 31 and the text mark 32 can also be formed using the same process as that of the fine pattern 33.

As such, the semiconductor device according to the first embodiment can be manufactured.

Next, the effect of the semiconductor device according to the embodiment will be described using a comparative example.

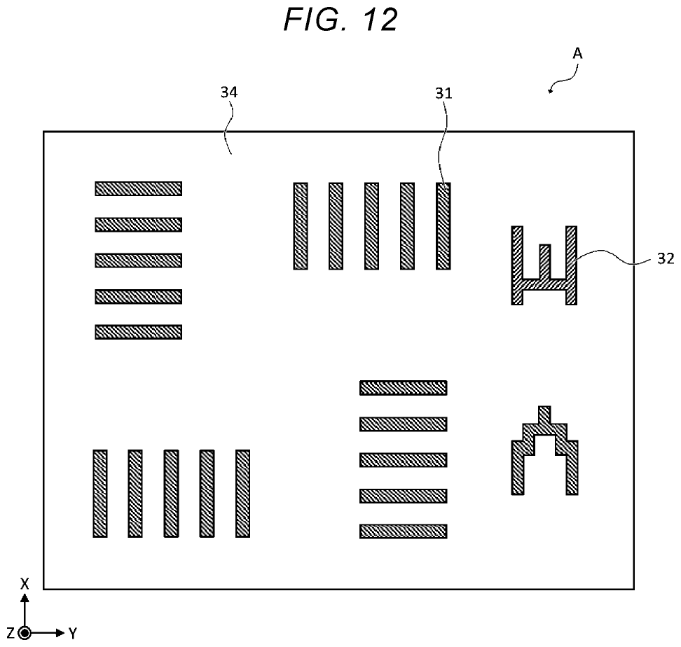

FIG. 12 is a diagram illustrating a layout of an alignment mark in a semiconductor device according to a first comparative example. As illustrated in FIG. 12, the alignment mark in the semiconductor device according to the first comparative example includes the mark 31 and the text mark 32 in an alignment mark area 3. As compared to the alignment mark according to the first embodiment, the alignment mark in the semiconductor device according to the first comparative example does not include the fine pattern 33, and an area excluding the mark 31 and the text mark 32 is covered with the interlayer insulating film 34. That is, as compared to the first embodiment, a wider area is configured by the interlayer insulating film 34. The mark 31 and the text mark 32 have the same stacked structure as the memory cell 10 as in the first embodiment.

The alignment mark in the semiconductor device according to the first comparative example has a characteristic in that the interlayer insulating film 34 is excessively polished into a curved shape by CMP that is performed after the formation of the interlayer insulating film 34 such that dishing is likely to occur. The reason is that a polishing rate of CMP for the interlayer insulating film 34 is higher than that of the stacked structure forming the mark 31 and the text mark 32. When dishing occurs, there may be an adverse effect such as defocusing of alignment by subsequent lithography.

On the other hand, as illustrated in FIG. 4, in the alignment mark in the semiconductor device according to the first embodiment, the fine pattern 33 is provided in the area excluding the mark 31 and the text mark 32. The area excluding the mark 31, the text mark 32, and the fine pattern 33 is covered with the interlayer insulating film 34 as in the first comparative example. As a result, the stacked structure forming the fine pattern 33 functions as a stopper of polishing by CMP. The area covered with the interlayer insulating film 34 can be decreased by the disposition of the fine pattern 33. Therefore, the curved surface formed by polishing can be made shallow and narrow, and the occurrence of dishing can be reduced.

### First Modification Example

Next, a first modification example of the first embodiment will be described with reference to FIG. 13.

In the first modification example, as illustrated in FIG. 13, the fine pattern 33 is disposed in the outer circumference portion of the area A and between the mark 31 and the text mark 32. By such disposition, the same effect as that of the first embodiment can be obtained at least in the vicinity of the area where the fine pattern 33 is disposed.

### Second Modification Example

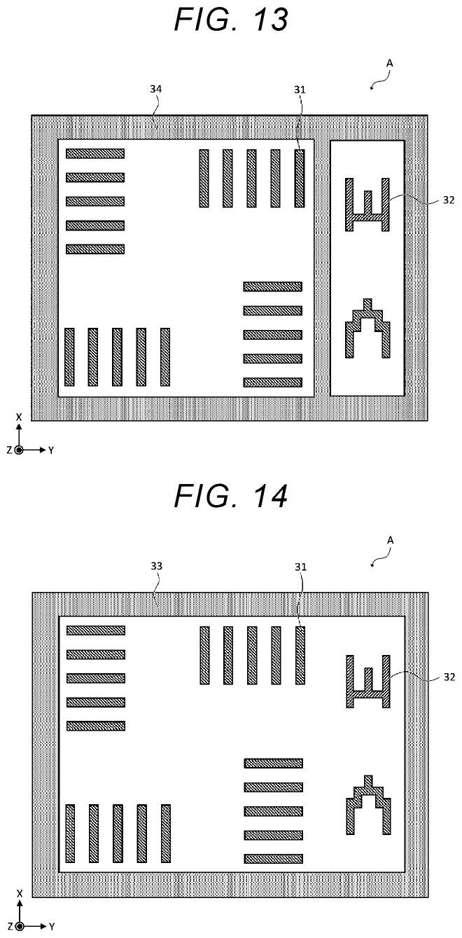

Next, a second modification example of the first embodiment will be described with reference to FIG. 14.

In the second modification example, as illustrated in FIG. 14, the fine pattern 33 may be disposed only in the outer circumference portion of the area A. By such disposition, the same effect as that of the first embodiment can be obtained in the vicinity of the area where the fine pattern 33 is disposed.

### Second Embodiment

Hereinafter, an alignment mark in a semiconductor device 1 according to a second embodiment will be described with reference to FIG. 15. FIG. 15 is a diagram illustrating a layout of the alignment mark according to the second embodiment and is an enlarged top view illustrating the area A of FIG. 1. A configuration other than the alignment mark is the same as that of the first embodiment.

As illustrated in FIG. 15, the alignment mark in the semiconductor device 1 according to the second embodiment includes a mark 41, a text mark 42, and the fine pattern 33. The mark 41 is an index for alignment. The text mark 42 is provided for identifying the mark. FIG. 15 illustrates an example where the text mark 42 is provided, but the text mark 42 is not essential. In the alignment mark according to the second embodiment, the mark 41 and the text mark 42 are configured by an interlayer insulating film, and the fine pattern 33 is located in a direction along the outer periphery of the mark 41 and the text mark 42. The interlayer insulating film includes, for example, an insulating material such as a silicon oxide film.

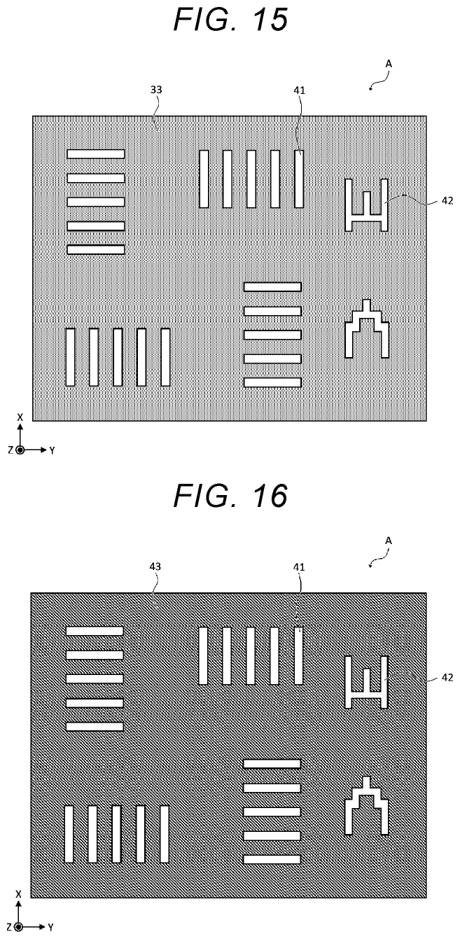

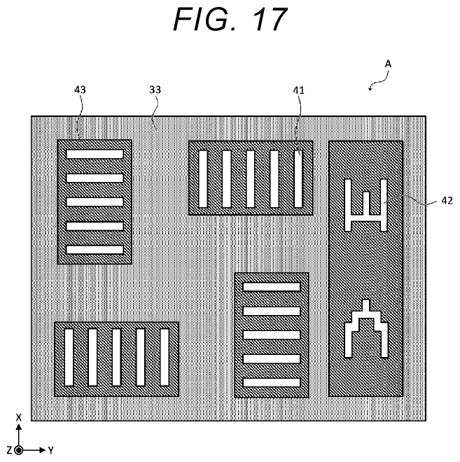

Next, the effect of the semiconductor device 1 according to the second embodiment will be described using a comparative example. FIG. 16 is a diagram illustrating an alignment mark in a semiconductor device according to a comparative example. As illustrated in FIG. 16, the alignment mark in the semiconductor device according to the comparative example does not include the fine pattern 33, and a stacked structure 43 that is the same as the memory cell 10 is in contact with the mark 41 and the text mark 42. The alignment mark in the semiconductor device according to the comparative example has a characteristic in that film peeling is likely to occur between the resistance change film 24 and the conductive film 25 of the memory cell 10 by CMP that is performed after the formation of the interlayer insulating film 34. The reason is that the adhesion between the resistance change film 24 and the conductive film 25 is low. Slippage occurs at an interface between the resistance change film 24 and the conductive film 25 by CMP, which causes film peeling. The slippage at the interface between the resistance change film 24 and the conductive film 25 is more likely to occur as the area occupied by the stacked structure 43 increases.

On the other hand, as illustrated in FIG. 15, in the alignment mark in the semiconductor device 1 according to the second embodiment, the fine pattern 33 that is divided in a matrix shape or in a linear shape is provided instead of the stacked structure 43. Therefore, the occurrence of the slippage at the interface between the resistance change film 24 and the conductive film 25 by CMP can be reduced.

### Modification Example

Next, a modification example of the semiconductor device 1 according to the second embodiment will be described with reference to FIG. 17.

In the modification example, as illustrated in FIG. 17, the fine pattern 33 is disposed at a position distant from the mark 41 and the text mark 42. The stacked structure 43 that is the same as the memory cell 10 is provided between the mark 41 and the fine pattern 33 and between the text mark 42 and the fine pattern 33. That is, the configuration of the mark 41 and the interlayer insulating film 34 (refer to FIG. 4) in the alignment mark according to the second embodiment is opposite to that of the alignment mark according to the first embodiment. The same effect as that of the second embodiment can be obtained in the vicinity of the area where the fine pattern 33 is disposed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor substrate including a first area and a second area;
a plurality of memory cells provided in the first area;
a mark provided in the second area and having a first side surface and a second side surface that intersects with the first side surface; and
a plurality of patterns provided in the second area and provided on the first side surface and the second side surface.

2. The semiconductor device according to claim 1, wherein
the plurality of patterns are formed as a linear shape.

3. The semiconductor device according to claim 1, wherein
the plurality of patterns are formed as a matrix shape.

4. The semiconductor device according to claim 1, wherein
a width of each of the plurality of patterns is less than a width of the mark.

5. The semiconductor device according to claim 1, wherein
a width of each of the plurality of patterns is equal to or less than about 10 μm.

6. The semiconductor device according to claim 1, wherein
the plurality of patterns and the memory cells have the same stacked structure.

7. The semiconductor device according to claim 1, wherein
a distance between the mark and the plurality of patterns is equal to or more than about 2.5 μm and equal to or less than about 4 μm.

8. The semiconductor device according to claim 1, wherein
the mark includes an insulating film.

9. The semiconductor device according to claim 1, wherein
the first area is a chip area and the second area is a kerf area interposed between the first area and another first area.

10. The semiconductor device according to claim 1, wherein
the mark includes one or more alignment marks.

11. A semiconductor device comprising:
a semiconductor substrate including a plurality of first areas and a second area, the second area interposed between adjacent ones of the plurality of first areas;
a plurality of memory arrays provided in the first areas, respectively;
a mark provided in the second area and having a first side surface and a second side surface that intersects with the first side surface; and
a plurality of patterns provided in the second area and provided on the first side surface and the second side surface.

12. The semiconductor device according to claim 11,
wherein
the plurality of patterns are formed as a linear shape.

13. The semiconductor device according to claim 11,
wherein
the plurality of patterns are formed as a matrix shape.

14. The semiconductor device according to claim 11,
wherein
a width of each of the plurality of patterns is less than a width of the mark.

15. The semiconductor device according to claim 11,
wherein
a width of each of the plurality of patterns is equal to or less than about 10 μm.

16. The semiconductor device according to claim 11,
wherein
the plurality of patterns and cells of the memory arrays have the same stacked structure.
